(19) United States
(12) Patent Application Publication
(10) Pub. No.: US 2026/0352155 A1
(43) Pub. Date: Nov. 5, 2026

(54) Vibration Device

(71) Applicant: SEIKO EPSON CORPORATION, Tokyo (JP)

(72) Inventor: Yusuke MATSUZAWA, Chino (JP)

(21) Appl. No.: 19/662,398

(22) Filed: Apr. 29, 2026

(30) Foreign Application Priority Data
Apr. 30, 2025 (JP) 2025-075233

(51) Int. Cl. H03B 5/36; H03B 5/04

(52) U.S. Cl. CPC H03B 5/364; H03B 5/04; H03B 2200/0018

(57) ABSTRACT

A vibration device includes: a semiconductor substrate including through electrodes; a wiring layer that is provided on a lower surface of the semiconductor substrate, includes at least four conductive layers each stacked via an insulating film, and has a conductive portion electrically connected to one of the through electrodes, a conductive portion electrically connected to the other one of the through electrodes, and conductive portions in the conductive layers; a terminal group including a terminal connected to the conductive portion and to which VDD supplied, a terminal connected to the conductive portion and to which VSS is supplied, a terminal connected to the conductive portion and to which a control signal is input, and a terminal connected to the conductive portion and from which an output signal is output, the terminal group being provided on a side opposite to the wiring layer of the semiconductor substrate; and a vibration element that is located on an upper surface side of the semiconductor substrate and connected to the through electrodes via bonding members, respectively.

The present application is based on, and claims priority from JP Application Serial Number 2025-075233, filed Apr. 30, 2025, the disclosure of which is hereby incorporated by reference herein in its entirety.

### BACKGROUND

### 1. Technical Field

The present disclosure relates to a vibration device.

### 2. Related Art

JP-A-2004-128591 discloses a piezoelectric oscillator including a piezoelectric vibrator in which an excitation electrode is formed on a piezoelectric element plate and a semiconductor integrated component in which an oscillation circuit is formed. In the disclosed piezoelectric oscillator, the piezoelectric vibrator is directly mounted on and connected to the semiconductor integrated component, and a lid is disposed so as to cover the piezoelectric vibrator from above the semiconductor integrated component. The disclosed piezoelectric oscillator is mounted on a user's mounting substrate by a connection electrode disposed on a surface opposite to a mounting surface of the piezoelectric vibrator of the semiconductor integrated component.

In such an oscillator, further deepening of a technique for realizing miniaturization is required.

### SUMMARY

A vibration device according to one aspect of the present disclosure includes: a semiconductor substrate that has a first surface and a second surface in an obverse and reverse relationship with each other, and includes a first through electrode and a second through electrode penetrating through the first surface and the second surface; a wiring layer that is provided on the second surface of the semiconductor substrate, includes at least four conductive layers each stacked via an insulating film, and has a first conductive portion electrically connected to the first through electrode, a second conductive portion electrically connected to the second through electrode, a third conductive portion, a fourth conductive portion, a fifth conductive portion, and a sixth conductive portion in the at least four conductive layers; a terminal group including a first terminal connected to the third conductive portion and to which a first potential is supplied, a second terminal connected to the fourth conductive portion and to which a second potential different from the first potential is supplied, a third terminal connected to the fifth conductive portion and to which a control signal is input, and a fourth terminal connected to the sixth conductive portion and from which an output signal is output, the terminal group being provided on a side opposite to the wiring layer of the semiconductor substrate; and a vibration element located on a side of the first surface of the semiconductor substrate and connected to the first through electrode and the second through electrode via bonding members, respectively.

### BRIEF DESCRIPTION OF THE DRAWINGS

FIG. 1 is a top perspective view of a vibration device according to the present embodiment.

FIG. 2 is a bottom perspective view of the vibration device.

FIG. 3 is a cross-sectional view of the vibration device taken along line III-III of FIG. 1.

FIG. 4 is a cross-sectional view of the vibration device taken along line IV-IV of FIG. 1.

FIG. 5 is a plan view showing wirings and a wiring layer of a base substrate of the vibration device.

FIG. 6 is a block diagram showing a circuit configuration of the vibration device.

FIG. 7 is a flow chart showing a manufacturing step of the vibration device.

FIG. 8 is a cross-sectional view showing an aspect of the vibration device in the manufacturing step.

FIG. 9 is a cross-sectional view showing an aspect of the vibration device in the manufacturing step.

FIG. 10 is a cross-sectional view showing an aspect of the vibration device in the manufacturing step.

### DESCRIPTION OF EMBODIMENTS

Hereinafter, an embodiment of the present disclosure will be described with reference to the drawings.

In each of the following drawings, in order to make each component easier to see, the scale of the dimension may be different depending on the component.

In addition, hereinafter, for convenience of description, three axes orthogonal to each other are set as an X axis, a Y axis, and a Z axis, and a direction parallel to the X axis is referred to as an “X-axis direction”, a direction parallel to the Y axis is referred to as a “Y-axis direction”, and a direction parallel to the Z axis is referred to as a “Z-axis direction”.

Further, the tip end side of each axis in the arrow direction is referred to as a “plus side”, and the opposite side is referred to as a “minus side”.

A view from the plus side in the Z-axis direction toward the minus side in the Z-axis direction is referred to as a “plan view”.

A surface on the plus side in the Z-axis direction is referred to as an “upper surface”, and a surface on the minus side in the Z-axis direction is referred to as a “lower surface”.

### 1. Embodiment 1

### 1.1. Schematic Configuration of Vibration Device

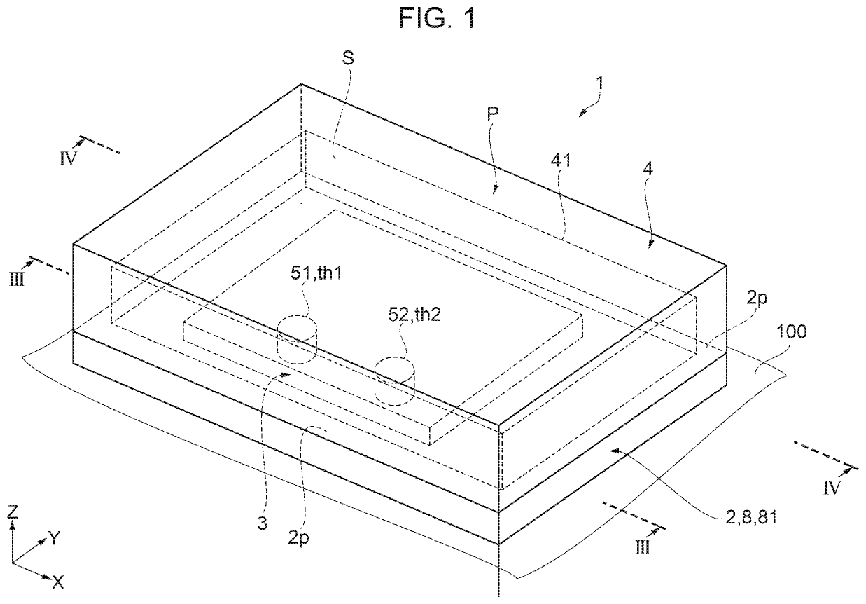

FIGS. 1 to 6 show a configuration of a vibration device 1 according to the present embodiment.

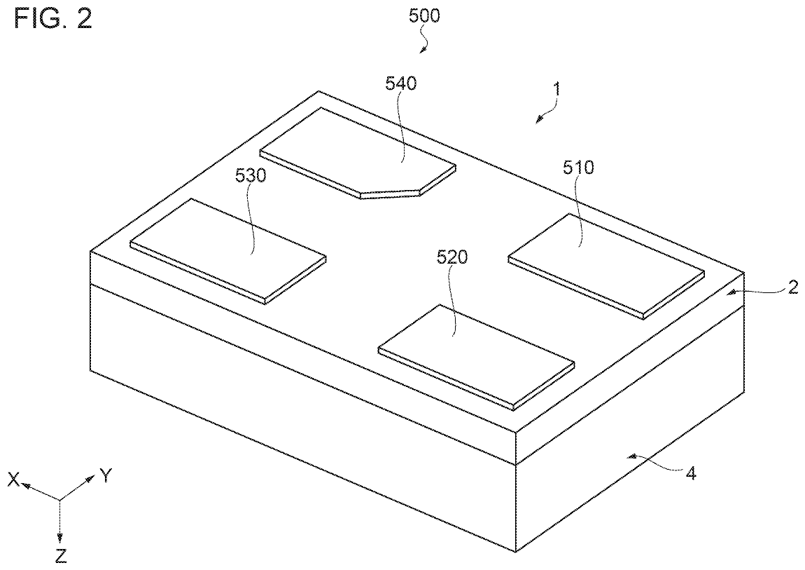

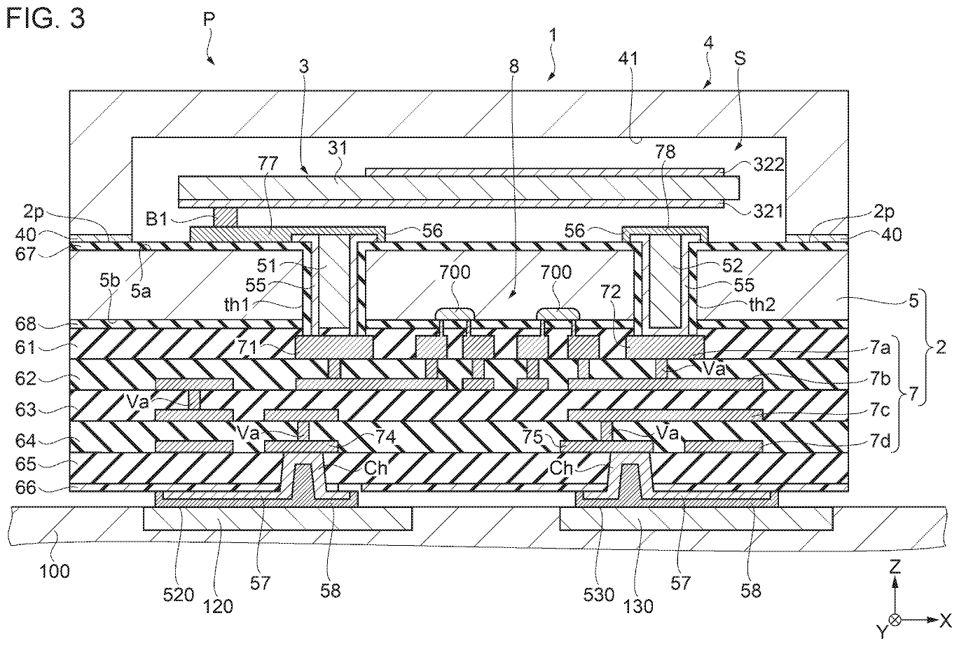

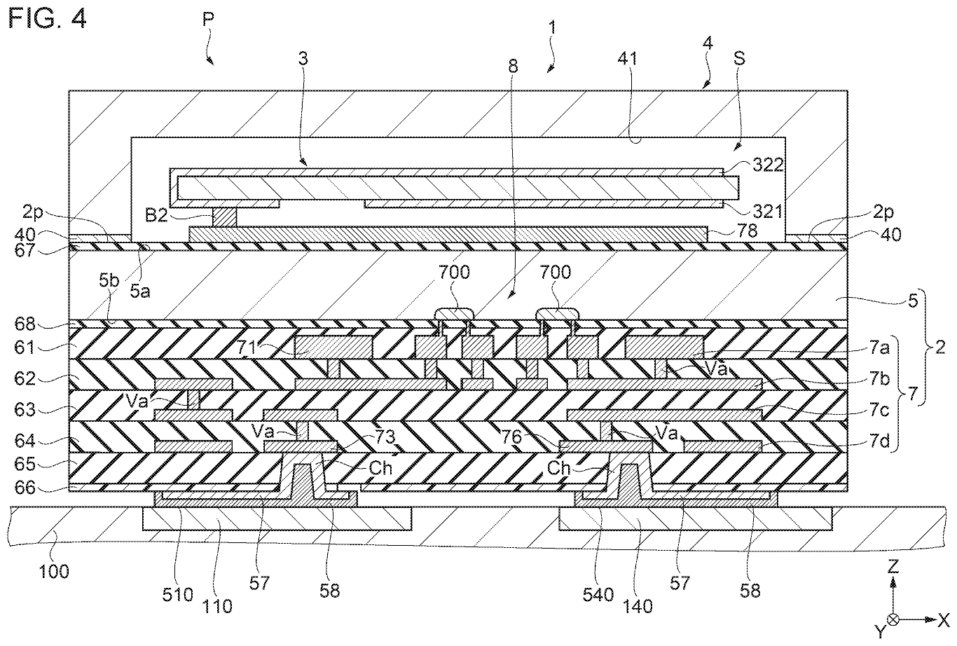

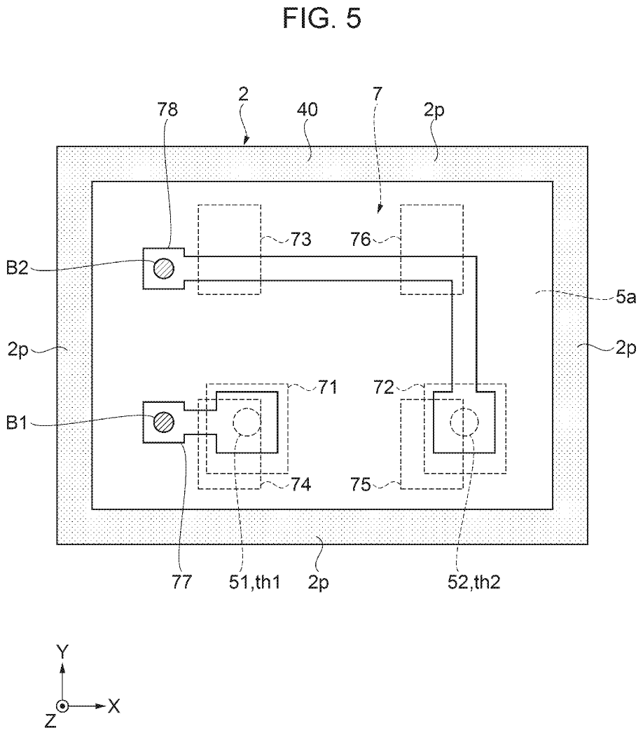

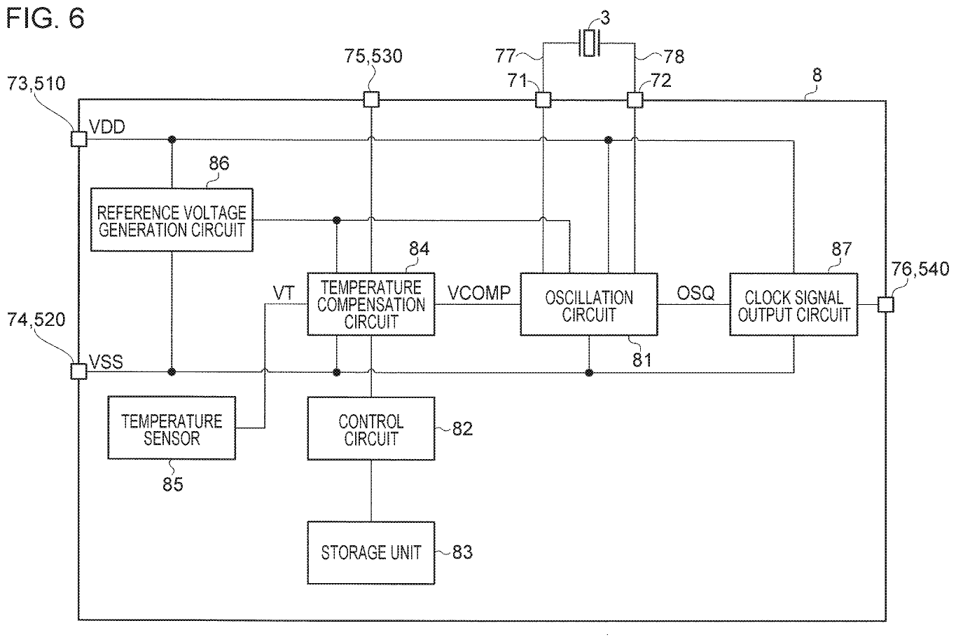

FIG. 1 is a top perspective view of the vibration device 1 according to the present embodiment as viewed from above. FIG. 2 is a lower perspective view of the vibration device 1 as viewed from below. FIG. 3 is a cross-sectional view of the vibration device 1 taken along line III-III of FIG. 1. FIG. 4 is a cross-sectional view of the vibration device 1 taken along line IV-IV of FIG. 1. FIG. 5 is a plan view showing wirings 77 and 78 and a wiring layer 7 of a base substrate 2 of the vibration device 1. FIG. 6 is a block diagram showing a circuit configuration of the vibration device 1.

The vibration device 1 according to the present embodiment is a vibration device using wafer level packaging (WLP). In the vibration device 1 using the WLP, since an IC itself is packaged, it is possible to maximize the area of the IC, that is, an integrated circuit 8, and it is possible to realize a small and highly functional oscillator and the like. In the vibration device using a ceramic package, the area of the IC in a plan view is, for example, 50 to 60% or less of the area of the ceramic package. On the other hand, according to the vibration device 1 using the WLP, it is possible to make the area of the integrated circuit 8 in the plan view larger than 50 to 60% of the area of the base substrate 2. As a result, it is possible to provide a circuit block for making the vibration device 1 more highly functional in the integrated circuit 8.

As shown in FIG. 1, the vibration device 1 includes the base substrate 2, a vibration element 3, and a lid body 4. In the present embodiment, the vibration device 1 is an oscillator. More specifically, the vibration device 1 is a quartz crystal oscillator in which the vibration element 3 made of quartz crystal and the integrated circuit 8 including an oscillation circuit 81 are integrated into one package. The vibration device 1 is mounted on, for example, a substrate 100 of an electronic device such as a mobile phone, and outputs a reference signal to the substrate 100. The vibration device 1 may be a micro electro mechanical systems (MEMS) oscillator. Further, the vibration device 1 may be a sensor such as an inertial sensor like a gyro sensor or an acceleration sensor, or a force sensor like an inclination sensor.

### 1.2. Configuration of Base Substrate 2

As shown in FIGS. 3 and 4, the base substrate 2 includes a semiconductor substrate 5 having an upper surface 5a and a lower surface 5b in an obverse and reverse relationship with each other, the wiring layer 7 provided on the lower surface 5b of the semiconductor substrate 5, and a terminal group 500 provided on the lower surface of the wiring layer 7. In the present embodiment, the upper surface 5a of the semiconductor substrate 5 is an example of a first surface, and the lower surface 5b of the semiconductor substrate 5 is an example of a second surface.

The terminal group 500 is external connection terminals of the vibration device 1, and includes, as shown in FIG. 2, four terminals 510, 520, 530, and 540 in the present embodiment. In the present embodiment, the terminal 510 is an example of a first terminal, the terminal 520 is an example of a second terminal, the terminal 530 is an example of a third terminal, and the terminal 540 is an example of a fourth terminal.

### 1.2.1. Semiconductor Substrate 5

The semiconductor substrate 5 is a silicon substrate. The semiconductor substrate 5 may be a substrate made of a semiconductor material other than silicon, such as Ge, GaP, GaAs, or InP.

As shown in FIGS. 3 and 4, a plurality of transistors 700 are provided on the wiring layer 7 side of the semiconductor substrate 5. The plurality of transistors 700 and the wiring layer 7 form the integrated circuit 8 including a plurality of circuit blocks.

The semiconductor substrate 5 includes through electrodes 51 and 52 respectively provided in through silicon vias th1 and th2 penetrating the upper surface 5a and the lower surface 5b. In the present embodiment, the through electrode 51 is an example of a first through electrode, and the through electrode 52 is an example of a second through electrode.

A passivation film 67 is provided on the upper surface 5a of the semiconductor substrate 5. The passivation film 67 is also provided on the inner peripheral surfaces of the through silicon vias th1 and th2. A passivation film 68 is provided on the lower surface 5b of the semiconductor substrate 5. The passivation films 67 and 68 are, for example, silicon oxide (SiO₂). The passivation film 67 may be a resin such as polyimide.

Each of the through electrodes 51 and 52 is a copper (Cu) plated electrode formed by an electrolytic plating method. In the present embodiment, each of the through electrodes 51 and 52 is formed by via embedding plating, but may be formed by conformal plating.

A seed layer 55 is provided between each of the through electrodes 51 and 52 and the passivation film 67. The seed layer 55 has two-layer laminated structure composed of a titanium (Ti) sputtered film and a copper sputtered film.

As shown in FIG. 5, the wiring 77 and the wiring 78 are provided on the upper surface 5a of the semiconductor substrate 5. The wiring 77 is provided at a position corresponding to the through electrode 51 and a bonding member B1, and electrically connects the through electrode 51 and the bonding member B1. The wiring 78 is provided at a position corresponding to the through electrode 52 and a bonding member B2, and electrically connects the through electrode 52 and the bonding member B2.

The bonding members B1 and B2 have conductivity and bond the vibration element 3 to the wirings 77 and 78, respectively. In the present embodiment, the bonding members B1 and B2 are bumps formed by electroless plating.

### 1.2.2. Wiring Layer 7

The wiring layer 7 includes insulating films 61, 62, 63, 64, and 65 and four conductive layers 7a, 7b, 7c, and 7d individually provided in between the insulating films 61, 62, 63, 64, and 65. The conductive layers 7a, 7b, 7c, and 7d are electrically connected to each other by vias Va respectively penetrating the insulating films 62, 63, and 64 provided between the layers. The conductive layers 7a, 7b, 7c, and 7d are, for example, metallic layers of aluminum.

The conductive layers 7a, 7b, 7c, and 7d are stacked in this order from the lower surface 5b of the semiconductor substrate 5. That is, in the wiring layer 7, the conductive layer 7a is a conductive film formed first (hereinafter, referred to as a lowermost conductive film) and is disposed closest to the semiconductor substrate 5. The conductive layer 7d is a conductive layer of a conductive film formed last (hereinafter referred to as an uppermost conductive film), and is disposed closest to the terminal group 500.

The wiring layer 7 is used for signal transmission and power supply in the integrated circuit 8, and preferably has at least four conductive layers in order to realize miniaturization by three-dimensional crossing. In the wiring layer 7, the number of conductive layers is preferably four or five, but the number of conductive layers may be six or more when the number of circuit blocks of the integrated circuit 8 increases by increasing the number of functions of the integrated circuit 8, making the integrated circuit 8 more highly functional, or the like.

In the wiring layer 7, the conductive layer on the uppermost layer side is used for long-distance signal transmission and power supply, and the conductive layer on the lowermost layer side is used for short-distance signal transmission and power supply. For example, the lowermost conductive layer on the transistor 700 side is used as a local wiring, and connects the source, the drain, and the gate of the transistor 700. The conductive layer on the uppermost layer side connects the local wiring and a global wiring as an intermediate wiring, and is used for medium-distance signal transmission and power supply. The intermediate wiring may include a conductive layer mainly including a wiring extending in the X-axis direction and a conductive layer mainly including a wiring extending in the Y-axis direction. The conductive layer on the uppermost layer side performs long-distance signal transmission as the global wiring. For example, the intermediate wiring may be a wiring in each circuit block of the integrated circuit 8, and the global wiring may be a wiring between the circuit blocks. A power supply wiring on a low potential side may be formed in two adjacent layers of the four conductive layers, and a power supply wiring on a high potential side may be formed in the other two different layers. When the power supply wiring is formed using a plurality of conductive layers, power supply can be stabilized. An inductor may be formed in the lowermost conductive layer.

The conductive layer 7a includes a conductive portion 71 and a conductive portion 72. The conductive portion 71 is electrically connected to an excitation electrode 321 of the vibration element 3 via the through electrode 51, the wiring 77, and the bonding member B1. The conductive portion 72 is electrically connected to an excitation electrode 322 of the vibration element 3 via the through electrode 52, the wiring 78, and the bonding member B2. In the present embodiment, the conductive portion 71 is an example of a first conductive portion, and the conductive portion 72 is an example of a second conductive portion.

In the present embodiment, the lowermost conductive layer 7a is made thicker than the other conductive layers 7b, 7c, and 7d. The conductive layer 7a includes the conductive portions 71 and 72, and the through silicon vias th1 and th2 are respectively provided at positions corresponding to the conductive portions 71 and 72 in a plan view. That is, by making the conductive layer 7a thicker, it is possible to suppress the possibility that the through silicon vias th1 and th2 respectively penetrate the conductive portions 71 and 72 when etching is performed to form the through silicon vias th1 and th2 at which the conductive portions 71 and 72 are respectively exposed. Therefore, the through silicon vias th1 and th2 can be easily formed, and the productivity can be improved.

The conductive layer 7d includes conductive portions 73, 74, 75, and 76. The conductive portion 73 is electrically connected to the terminal 510 via a contact hole Ch. The conductive portion 74 is electrically connected to the terminal 520 via a contact hole Ch. The conductive portion 75 is electrically connected to the terminal 530 via a contact hole Ch. The conductive portion 76 is electrically connected to the terminal 540 via a contact hole Ch. In the present embodiment, the conductive portion 73 is an example of a third conductive portion, the conductive portion 74 is an example of a fourth conductive portion, the conductive portion 75 is an example of a fifth conductive portion, and the conductive portion 76 is an example of a sixth conductive portion.

The terminals 510, 520, 530, and 540 are external connection terminals of the vibration device 1. The terminals 510, 520, 530, and 540 are respectively bonded to mounting terminals 110, 120, 130, and 140 of the substrate 100 of the electronic device.

The terminal 510 is a terminal to which a high-potential-side power supply potential (VDD) is supplied. The terminal 520 is a terminal to which a low-potential-side power supply potential (VSS) is supplied. The terminal 530 is a terminal for inputting an output enable signal OE. The terminal 540 is a terminal for outputting a clock signal CK. Each of the terminals 510, 520, 530, and 540 includes a conductive layer 57 and a conductive layer 58. The conductive layer 57 contains titanium and copper, and the conductive layer 58 contains titanium and gold. The number of external connection terminals is not limited to four. In the present embodiment, the VDD is an example of a first potential, and the VSS is an example of a second potential.

### 1.2.3. Integrated Circuit 8

The base substrate 2 has the integrated circuit 8. The integrated circuit 8 is provided on the lower surface 5b side of the semiconductor substrate 5. In other words, the integrated circuit 8 is provided between the semiconductor substrate 5 and the terminal group 500. In the present embodiment, such a configuration in which the integrated circuit 8 is provided on the lower surface 5b side of the semiconductor substrate 5 is referred to as a face-down system. On the contrary, a configuration in which the integrated circuit 8 is provided on the upper surface 5a side of the semiconductor substrate 5 is referred to as a face-up system.

As shown in FIG. 6, the integrated circuit 8 includes the oscillation circuit 81, a control circuit 82, a storage unit 83, a temperature compensation circuit 84, a temperature sensor 85, a reference voltage generation circuit 86, and a clock signal output circuit 87.

The oscillation circuit 81 is a circuit that generates an oscillation signal using the vibration element 3. The oscillation circuit 81 is electrically connected to the vibration element 3 via the conductive portion 71, the wiring 77, the wiring 78, and the conductive portion 72. The oscillation circuit 81 generates the oscillation signal by oscillating the vibration element 3. For example, in a temperature compensated crystal oscillator (TCXO) or an oven controlled crystal oscillator (OCXO), a control voltage VCOMP corresponding to a detected temperature is input to the oscillation circuit 81, and the oscillation circuit 81 causes the vibration element 3 to oscillate at an oscillation frequency corresponding to the control voltage VCOMP. The control voltage VCOMP is a temperature compensation voltage that compensates for the temperature characteristics of the oscillation frequency.

The clock signal output circuit 87 outputs a clock signal to the terminal 540 via the conductive portion 76 based on an oscillation signal OSQ of the oscillation circuit 81. The clock signal output circuit 87 buffers the oscillation signal OSQ or a signal obtained by dividing the oscillation signal OSQ, and outputs the buffered signal as a clock signal. In the present embodiment, the clock signal is an example of an output signal.

The control circuit 82 controls each section of the integrated circuit 8. The control circuit 82 also performs interface processing with an external CPU or the like. The control circuit 82 is realized by, for example, a logic circuit such as a gate array.

The storage unit 83 stores various kinds of information necessary for the operation of the integrated circuit 8. For example, a coefficient or the like of a polynomial for temperature compensation necessary for the temperature compensation circuit 84 to perform temperature compensation processing is stored. The storage unit 83 is, for example, a nonvolatile memory.

The temperature compensation circuit 84 outputs the control voltage VCOMP based on a temperature detection signal VT from the temperature sensor 85 and a control signal of an oscillation frequency input from the outside via the terminal 530 and the conductive portion 75.

The temperature sensor 85 is a sensor that detects the temperature of the vibration device 1. For example, the temperature sensor 85 can be constituted by a diode or the like. The temperature sensor 85 constituted by a diode performs temperature detection using the temperature dependence of the forward voltage of the diode, and outputs the temperature detection signal VT.

The reference voltage generation circuit 86 is a circuit that generates a power supply, a reference voltage, a bias voltage, a bias current, and the like to be supplied to each section of the integrated circuit 8. To the reference voltage generation circuit 86, the VDD is input via the terminal 510 and the conductive portion 73, and the VSS is input via the terminal 520 and the conductive portion 74. The reference voltage generation circuit 86 supplies a reference voltage to the temperature compensation circuit 84 or supplies a power supply voltage to the oscillation circuit 81.

### 1.3. Configuration of Vibration Element 3

As shown in FIGS. 3 and 4, the vibration element 3 includes a vibration substrate 31 and excitation electrodes 321 and 322.

The vibration substrate 31 has a thickness shear vibration mode, and is formed of an AT-cut quartz crystal substrate in the present embodiment. Since the AT-cut quartz crystal substrate has cubic frequency-temperature characteristics, the vibration element 3 having excellent temperature characteristics is obtained.

The excitation electrode 321 is disposed on the lower surface of the vibration substrate 31, and are electrically connected to the conductive portion 71 via the bonding member B1, the wiring 77, and the through electrode 51. The excitation electrode 322 is disposed on the upper surface of the vibration substrate 31, and a portion thereof is drawn to the lower surface of the vibration substrate 31 and is electrically connected to the conductive portion 72 via the bonding member B2, the wiring 78, and the through electrode 52.

The configuration of the vibration element 3 is not limited to the above-described configuration. For example, the vibration element 3 may have a mesa shape in which the vibration region interposed between the excitation electrodes 321 and 322 protrudes from the periphery thereof, or conversely, may have an inverted mesa shape in which the vibration region is recessed from the periphery thereof. In addition, bevel processing for grinding the periphery of the vibration substrate 31 or convex processing for forming the upper surface and the lower surface as convex curved surfaces may be performed. In addition, the vibration element 3 is not limited to a vibration element vibrating in the thickness shear vibration mode, and may be, for example, a vibration element in which a plurality of vibrating arms perform flexure vibration in an in-plane direction. That is, the vibration substrate 31 is not limited to being formed of the AT-cut quartz crystal substrate, and may be formed of a quartz crystal substrate other than the AT-cut quartz crystal substrate, for example, an X-cut quartz crystal substrate, a Y-cut quartz crystal substrate, a Z-cut quartz crystal substrate, a BT-cut quartz crystal substrate, an SC-cut quartz crystal substrate, an ST-cut quartz crystal substrate, or the like. In addition, in the present embodiment, the vibration substrate 31 is formed of quartz crystal, but the vibration substrate 31 is not limited thereto. For example, the vibration substrate 31 may be formed of a piezoelectric single crystalline body such as lithium niobate, lithium tantalate, lithium tetraborate, langasite, potassium niobate, or gallium phosphate, or may be formed of a piezoelectric single crystalline body other than these. Further, the vibration element 3 is not limited to a piezoelectric driving type vibration element, and may be an electrostatic driving type vibration element using an electrostatic force.

### 1.4. Configuration of Lid Body 4

The lid body 4 is a silicon substrate similarly to the semiconductor substrate 5. As a result, the linear expansion coefficients of the semiconductor substrate 5 and the lid body 4 become equal to each other, generation of thermal stress due to thermal expansion is suppressed, and the vibration device 1 having excellent vibration characteristics is obtained. Further, since the vibration device 1 can be formed by a semiconductor process, the vibration device 1 can be efficiently manufactured with high accuracy, and the miniaturization of the vibration device 1 can be achieved. However, the lid body 4 is not particularly limited, and for example, a substrate made of a semiconductor material other than silicon, such as Ge, GaP, GaAs, or InP, may be used.

As shown in FIGS. 3 and 4, the lid body 4 has a recessed portion 41 and is bonded to an outer peripheral portion 2p of the base substrate 2 to form a package P. The vibration element 3 is accommodated in an accommodation space S in the package P. The accommodation space S is airtight, and is in a decompressed state, preferably in a state closer to a vacuum. As a result, a viscous resistance is reduced, and an oscillation characteristic of the vibration element 3 is improved. However, an atmosphere of the accommodation space S is not particularly limited.

### 1.5. Method of Manufacturing Vibration Device 1

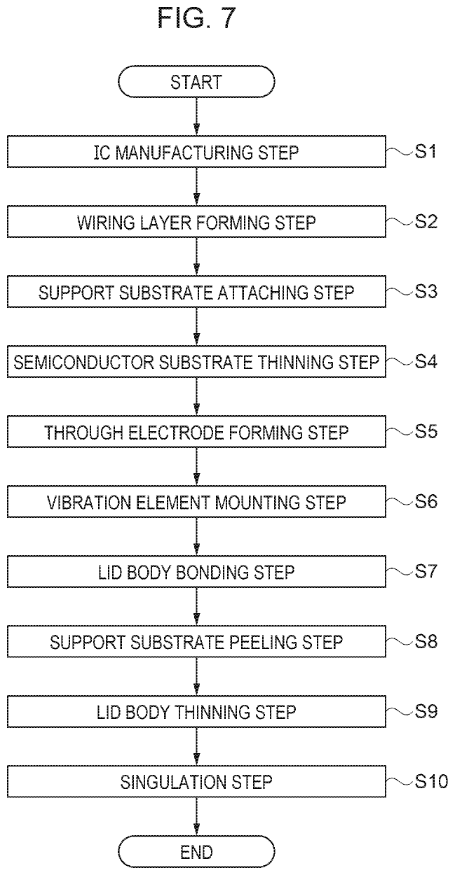

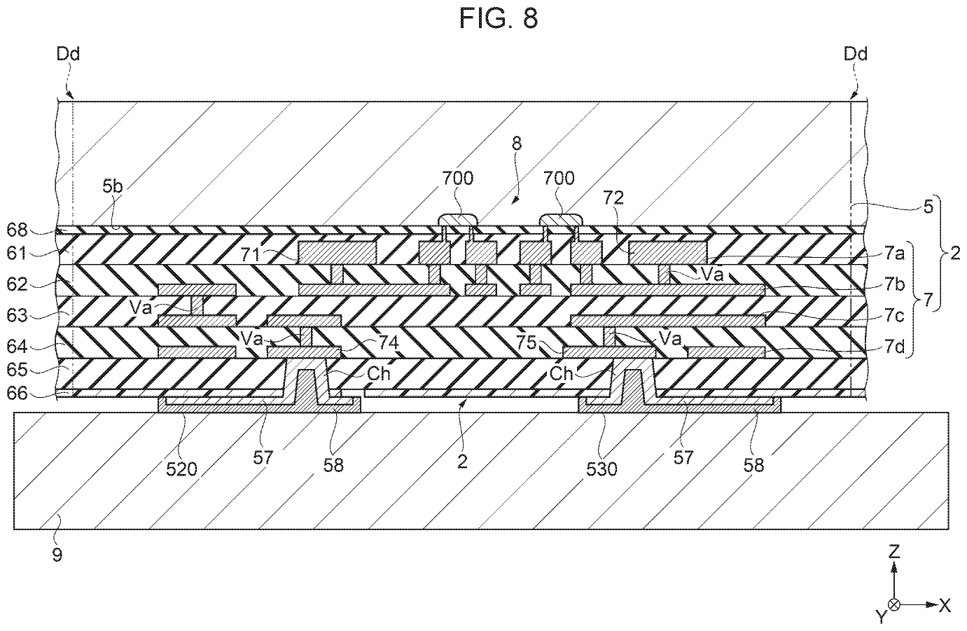

Next, a method of manufacturing the vibration device 1 according to the present embodiment will be described with reference to FIGS. 7 to 10. FIG. 7 is a flowchart for describing a manufacturing step of the vibration device 1 according to the present embodiment. FIGS. 8 to 10 are cross-sectional views each showing an aspect in the course of manufacture, and each cross-sectional view shows a cross section at a position corresponding to line III-III of FIG. 1.

As shown in FIG. 7, the method of manufacturing the vibration device 1 includes an IC manufacturing step S1, a wiring layer forming step S2, a support substrate attaching step S3, a semiconductor substrate thinning step S4, a through electrode forming step S5, a vibration element mounting step S6, a lid body bonding step S7, a support substrate peeling step S8, a lid body thinning step S9, and a singulation step S10. In the method of manufacturing the vibration device 1, the vibration device 1 is formed by using a semiconductor wafer.

In the IC manufacturing step S1, as shown in FIG. 8, the transistors 700 and the passivation film 68 are formed on the lower surface 5b side of the semiconductor substrate 5.

In the wiring layer forming step S2, the wiring layer 7 including the conductive layers 7a, 7b, 7c, and 7d, the insulating films 61, 62, 63, 64, and 65, the passivation film 66, and the vias Va is formed on the lower surface of the passivation film 68. Thus, the integrated circuit 8 including the plurality of transistors 700 and the wiring layer 7 is formed on the lower surface 5b side of the semiconductor substrate 5. Next, the contact holes Ch for respectively exposing the conductive portions 73, 74, 75, and 76 are formed, and the conductive layers 57 and 58 are formed and patterned to form the terminals 510, 520, 530, and 540.

The support substrate attaching step S3 is a wafer support system (WSS) process. In this step, a support substrate 9 is attached to the lower surface of the base substrate 2, which is a wafer, with an adhesive. By attaching the support substrate 9, the mechanical strength of the wafer can be maintained, and the semiconductor substrate 5 can be thinned.

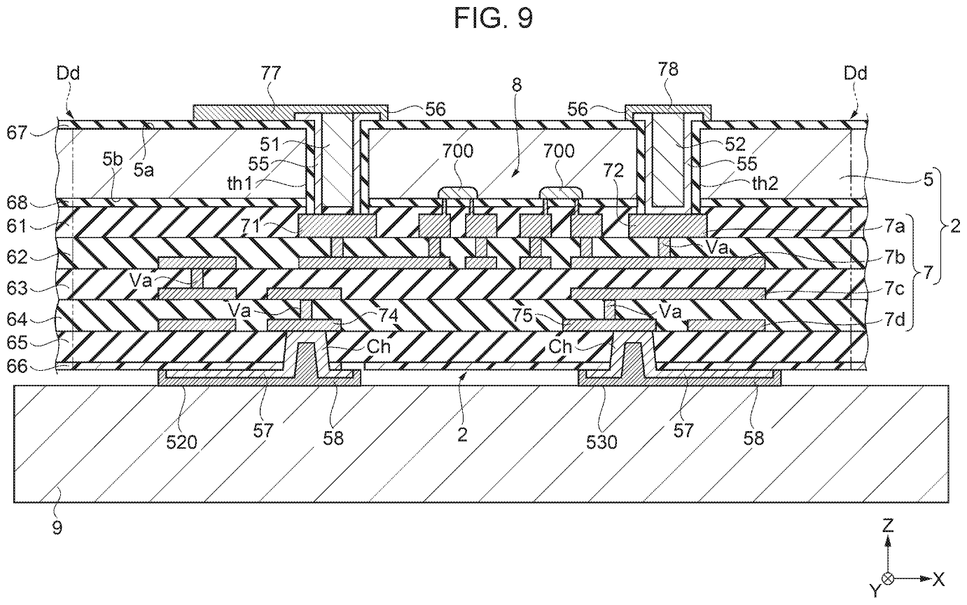

In the semiconductor substrate thinning step S4, as shown in FIG. 9, the semiconductor substrate 5 is ground and polished from the upper surface 5a side, and the thickness of the semiconductor substrate 5 is thinned to about 70 μm.

In the through electrode forming step S5, the through electrodes 51 and 52 each penetrating between the upper surface 5a and the lower surface 5b of the semiconductor substrate 5 are formed. First, the through silicon vias th1 and th2 penetrating through the semiconductor substrate 5 are respectively formed at positions corresponding to the conductive portions 71 and 72 of the conductive layer 7a. The conductive layer 7a in which the conductive portions 71 and 72 are provided is thicker than the other conductive layers 7b, 7c, and 7d. Therefore, it is possible to suppress the through silicon vias th1 and th2 from respectively penetrating through the conductive portions 71 and 72 due to the etching for forming the through silicon vias th1 and th2.

Next, the passivation film 67 is formed on the upper surface 5a of the semiconductor substrate 5 and the inner surfaces of the through silicon vias th1 and th2. Next, the passivation film 67 at the bottom of the through silicon vias th1 and th2 is removed, and the conductive portions 71 and 72 are respectively exposed at the bottom of the through silicon vias th1 and th2. Next, the seed layer 55 is formed so as to cover the passivation film 67 on the upper surface 5a of the semiconductor substrate 5 and the inner surfaces of the through silicon vias th1 and th2. Next, the through electrodes 51 and 52 are respectively formed in the through silicon vias th1 and th2.

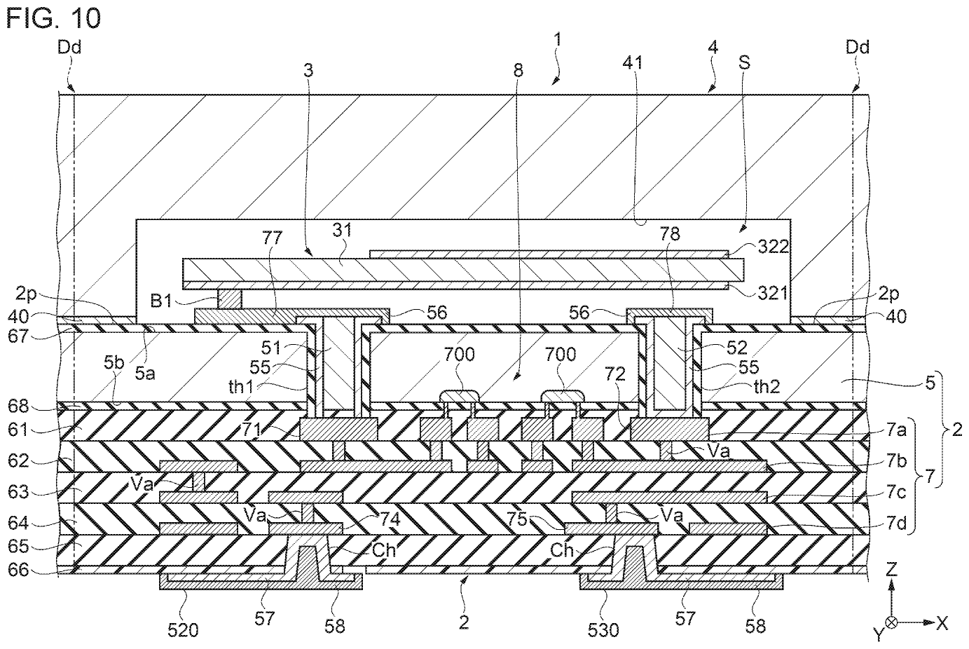

In the vibration element mounting step S6, as shown in FIG. 10, the vibration element 3 is mounted on the upper surface 5a of the semiconductor substrate 5. In this step, first, the wirings 77 and 78 and the bonding members B1 and B2 are formed, and the vibration element 3 is mounted on the bonding members B1 and B2.

In the lid body bonding step S7, the lid body 4 is bonded to the outer peripheral portion 2p of the upper surface 5a of the semiconductor substrate 5 via a bonding material 40 in a reduced pressure state, and the vibration element 3 is vacuum-sealed in the accommodation space S.

In the support substrate peeling step S8, the support substrate 9 is peeled.

In the lid body thinning step S9, the lid body 4 is ground and polished from the upper surface side, and the plate thickness of the lid body 4 is thinned to about 150 μm.

In the singulation step S10, the semiconductor wafer is cut at the positions of division lines Dd by a dicing saw or the like to be singulated into individual vibration devices 1. The lengths of the long sides in the plan view of the vibration device 1 are, for example, about 1.2 mm to 1.0 mm, and the lengths of the short sides are, for example, about 1.0 mm to 0.8 mm.

As described above, the vibration device 1 according to the present embodiment includes: the semiconductor substrate 5 that has the upper surface 5a as the first surface and the lower surface 5b as the second surface in an obverse and reverse relationship with each other, and includes the through electrode 51 as the first through electrode and the through electrode 52 as the second through electrode penetrating through the upper surface 5a and the lower surface 5b; the wiring layer 7 that is provided on the lower surface 5b of the semiconductor substrate 5, includes the at least four conductive layers 7a, 7b, 7c, and 7d each stacked via an insulating film, and has the conductive portion 71 as the first conductive portion electrically connected to the through electrode 51, the conductive portion 72 as the second conductive portion electrically connected to the through electrode 52, the conductive portion 73 as the third conductive portion, the conductive portion 74 as the fourth conductive portion, the conductive portion 75 as the fifth conductive portion, and the conductive portion 76 as the sixth conductive portion in the at least four conductive layers 7a, 7b, 7c, and 7d; the terminal group 500 including the terminal 510 as the first terminal connected to the conductive portion 73 and to which the VDD as the first potential is supplied, the terminal 520 as the second terminal connected to the conductive portion 74 and to which the VSS as the second potential different from the VDD is supplied, the terminal 530 as the third terminal connected to the conductive portion 75 and to which the control signal is input, and the terminal 540 as the fourth terminal connected to the conductive portion 76 and from which the output signal is output, the terminal group 500 being provided on a side opposite to the wiring layer 7 of the semiconductor substrate 5; and the vibration element 3 that is located on a side of the upper surface 5a of the semiconductor substrate 5 and connected to the through electrode 51 and the through electrode 52 via the bonding members B1 and B2, respectively.

As described above, the vibration device 1 according to the present embodiment has a configuration in which the wiring layer 7 includes the at least four conductive layers 7a, 7b, 7c, and 7d, and the at least four conductive layers 7a, 7b, 7c, and 7d include the conductive portions 71 and 72 each electrically connected to the vibration element 3 and the conductive portions 73, 74, 75, and 76 electrically connected to the terminal group 500. Therefore, it is possible to provide a configuration capable of realizing miniaturization. Further, it is also possible to realize, for example, maximization of the area of the integrated circuit 8 of the vibration device 1.

In the vibration device 1 according to the present embodiment, the transistors 700 are provided on the lower surface 5b side of the semiconductor substrate 5, and the conductive portion 71 and the conductive portion 72 are provided in the conductive layer 7a closest to the transistors 700 among the at least four conductive layers 7a, 7b, 7c, and 7d.

As described above, in the vibration device 1 according to the present embodiment, the conductive portion 71 and the conductive portion 72 are provided in the conductive layer 7a closest to the transistors 700. Therefore, it is possible to provide a configuration capable of realizing miniaturization. Further, it is also possible to realize, for example, maximization of the area of the integrated circuit 8 of the vibration device 1.

In the vibration device 1 according to the present embodiment, the conductive layer 7a in which the conductive portion 71 and the conductive portion 72 are provided is thicker than the other conductive layers 7b, 7c, and 7d.

As described above, in the vibration device 1 according to the present embodiment, the conductive layer 7a is thicker than the other conductive layers 7b, 7c, and 7d. Therefore, the through electrodes 51 and 52 can be easily formed, and the productivity can be improved.

In the vibration device 1 according to the present embodiment, the conductive portion 73, the conductive portion 74, the conductive portion 75, and the conductive portion 76 are provided in the conductive layer 7d farthest from the transistors 700 among the at least four conductive layers 7a, 7b, 7c, and 7d.

As described above, in the vibration device 1 according to the present embodiment, the conductive portion 73, the conductive portion 74, the conductive portion 75, and the conductive portion 76 are provided in the conductive layer 7d farthest from the transistors 700. Therefore, it is possible to provide a configuration capable of realizing miniaturization. Further, it is also possible to realize, for example, maximization of the area of the integrated circuit 8 of the vibration device 1.

The vibration device 1 according to the present embodiment includes the lid body 4 that is bonded to the semiconductor substrate 5 to form the accommodation space S for accommodating the vibration element 3 between the lid body 4 and the semiconductor substrate 5.

Therefore, according to the vibration device 1 of the present embodiment, it is possible to realize the vibration device 1 having a configuration suitable for miniaturization. Further, it is also possible to realize, for example, maximization of the area of the integrated circuit 8 of the vibration device 1.

Although the present disclosure has been described above based on the preferred embodiment, the present disclosure is not limited to the above-described embodiment. In addition, it is possible to replace the configuration of each section of the present disclosure with any configuration that exerts the same function as the above embodiment, and to add any configuration.

What is claimed is:

1. A vibration device comprising:
a semiconductor substrate that has a first surface and a second surface in an obverse and reverse relationship with each other, and includes a first through electrode and a second through electrode penetrating through the first surface and the second surface;
a wiring layer that is provided on the second surface of the semiconductor substrate, includes at least four conductive layers each stacked via an insulating film, and has a first conductive portion electrically connected to the first through electrode, a second conductive portion electrically connected to the second through electrode, a third conductive portion, a fourth conductive portion, a fifth conductive portion, and a sixth conductive portion in the at least four conductive layers;
a terminal group including a first terminal connected to the third conductive portion and to which a first potential is supplied, a second terminal connected to the fourth conductive portion and to which a second potential different from the first potential is supplied, a third terminal connected to the fifth conductive portion and to which a control signal is input, and a fourth terminal connected to the sixth conductive portion and from which an output signal is output, the terminal group being provided on a side opposite to the wiring layer of the semiconductor substrate; and
a vibration element that is located on a side of the first surface of the semiconductor substrate and connected to the first through electrode and the second through electrode via bonding members, respectively.

2. The vibration device according to claim 1, further comprising
transistors provided on a side of the second surface of the semiconductor substrate,
wherein the first conductive portion and the second conductive portion are provided in the conductive layer closest to the transistors among the at least four conductive layers.

3. The vibration device according to claim 2,
wherein the conductive layer in which the first conductive portion and the second conductive portion are provided is thicker than the other conductive layers.

4. The vibration device according to claim 2,
wherein the third conductive portion, the fourth conductive portion, the fifth conductive portion, and the sixth conductive portion are provided in the conductive layer farthest from the transistors among the at least four conductive layers.

5. The vibration device according to claim 1, further comprising
a lid body that is bonded to the semiconductor substrate to form an accommodation space for accommodating the vibration element between the lid body and the semiconductor substrate.
